(19) United States
(12) Patent Application Publication
(10) Pub. No.: US 2008/0231256 A1
(43) Pub. Date: Sep. 25, 2008

(54) Removable Front Panel Control for Oscilloscope

(75) Inventors: Tyler Cox, Westtown, NY (US); Anthony Cake, Givrins (CH); Sun Y. Kim, River Vale, NJ (US); John Pasichnyk, Chester, NY (US); Vrajesh Dave, New York, NY (US)

Correspondence Address: LECROY CORPORATION, 700 CHESTNUT RIDGE ROAD, CHESTNUT RIDGE, NY, 10977, US

(73) Assignee: LeCroy Corporation, Chestnut Ridge, NY (US)

(21) Appl. No.: 12/132,660

(22) Filed: Jun. 4, 2008

Related U.S. Application Data
(63) Continuation-in-part of application No. 11/641,154, filed on Dec. 19, 2006.
(60) Provisional application No. 61/025,937, filed on Feb. 4, 2008.

(51) Int. Cl. G01R 13/20

(52) U.S. Cl. 324/121 R

(57) ABSTRACT

A test and measurement apparatus is provided including a control panel. The control panel is removable and user-replaceable with an alternate control panel. The control panel can be connected to the test and measurement apparatus or to a generic local computing device to control and interact with the test and measurement apparatus.

### CROSS REFERENCE TO RELATED APPLICATIONS

This application claims the benefit under 35 USC 119 of U.S. Provisional Patent Application Ser. No. 61/025,937 filed Feb. 4, 2008, titled “Removable Front Panel Control for Oscilloscope”, currently pending, the contents thereof being incorporated herein by reference. This application is also a continuation in part application of U.S. patent application Ser. No. 11/641,154 filed Dec. 19, 2006, titled “Resizable Display”, currently pending, the contents thereof being incorporated herein by reference.

### FIELD OF THE INVENTION

This invention is related generally to the collection of control buttons and knobs (configured to be manipulated as a cohesive control panel) used for controlling a test and measurement instrument, and more particularly to such a control panel including the matrix of control buttons and knobs which can be removed from the intended device to be controlled. Most particularly, the invention is related to an oscilloscope with such a removable control panel to permit 1) user interchangeable controls to be implemented that are determined to be best suited for the user's particular application and 2) the ability to control the target device remotely using standard computing equipment over a network with the aid of the product's standard removable control panel, including the standard control buttons and knobs to which the user has become accustomed.

### BACKGROUND OF THE INVENTION

When controlling complex measurement equipment, it is well understood that the most commonly user-actuated commands and controls are assigned to pre-configured buttons and knobs configured into a matrix and typically placed within easy reach on the front of the instrument. Such a matrix is commonly referred to an instrument's control panel.

The debugging of electronic hardware requires a complex arrangement of test probes, cables and equipment connecting the device under test to the measurement equipment. These measurement instruments require a good deal of bench space for their footprint, and are constantly in competition with the object under test for scarce bench space. Unfortunately, the test and measurement device cannot be positioned too far from the device under test because the user must frequently interact with the control knobs and buttons in order to adjust the most frequently used settings of the test and measurement apparatus.

Complex test and measurement devices and oscilloscopes in particular, are by their very nature, multi-use instruments used for a variety of tasks. Manufacturers of these devices must therefore make careful tradeoffs about which functions to hard-code in the front panel controls. Some manufacturers offer different models of oscilloscopes which have controls designed for particular applications such as “disk drive analysis” or “serial data analysis”. These differing models have essentially the same hardware capabilities within the unit but simply differently configured front panel controls and software unique to the task at hand. The end user has no option to change or reconfigure the front panel controls if the immediate purpose of the unit changes over time.

In an attempt to address this issue, manufacturers have contemplated doing away with some of the hardware requirements, such as a control panel, in favor of a digitally displayed “soft” control panel shown to use on a portion of a display screen. Experience has shown that many if not most users of these devices prefer a hardware based display control with physical buttons and knobs.

The affection of end-users for physical knobs and buttons poses an additional dilemma for users that wish to control their instrument from a lengthy remote distance. Many test and measurement devices offer users the ability to control the device “remotely” through an electronic network such as Ethernet or GPIB. These devices permit transmission of commands and data to/from a generic local computing device such as a laptop or stationary computer. However the generic local computing device lacks the standard “short-cut” physical knobs and buttons that the user has become accustomed to using to control the instrument, thus decreasing the user's efficiency in using the device.

Therefore it would be beneficial to provide an improved apparatus that overcomes the drawbacks of the prior art.

Still other objects and advantages of the invention will in part be obvious and will in part be apparent from the specification and the drawings.

### SUMMARY OF THE INVENTION

Therefore, in accordance with the invention, a test and measurement apparatus is provided including a fully removable, user-changeable control panel.

The control panel may be attached to the test and measurement apparatus in a wired or wireless manner in order to retain the functionality of the panel, even when physically detached from the apparatus.

The control panel may be substituted by an alternate control panel with controls better suited for a particular application.

The control panel may be connected to the test a generic local computing device to provide the standard set of user controls when viewing or controlling the test and measurement device remotely.

The invention accordingly comprises the features of construction, combination of elements, and arrangement of parts which will be exemplified in the construction hereinafter set forth, and the scope of the invention will be indicated in the claims.

### BRIEF DESCRIPTION OF THE DRAWINGS

For a more complete understanding of the invention, reference is made to the following description and accompanying drawings, in which:

FIG. 1 depicts a representation of an oscilloscope in accordance with the invention in which a removable control panel is in place in a traditional manner;

FIG. 2 depicts the oscilloscope of FIG. 1 with the removable control panel replaced by an alternate control panel better suited for a different application.

FIG. 3 depicts the removable front panel connected to a local generic computing device and being used to control the oscilloscope of FIG. 1.

### DETAILED DESCRIPTION OF THE PREFERRED EMBODIMENTS

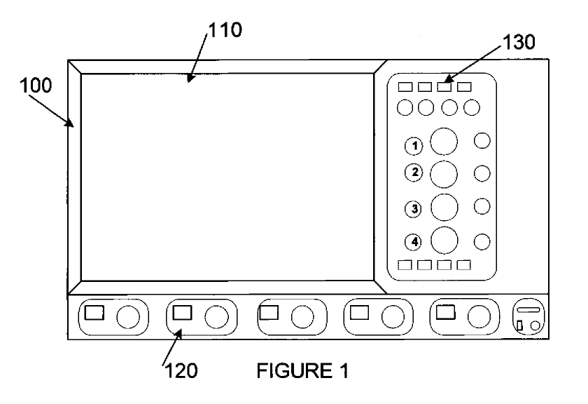

Referring first to FIG. 1, an oscilloscope 100 is shown. While the invention is described making reference to an oscilloscope, it should be understood that the invention is intended to apply to any type of test and measurement equipment, and to any apparatus including a display and an accompanying control panel. Oscilloscope 100 is preferably provided with a display 110, input/output ports 120 and a control panel 130. Control panel 130 includes knobs, indicators, buttons and the like as is well known in the industry. In FIG. 1, control panel 130 is depicted in a traditional location, thus providing a conventional oscilloscope layout. However, as will be discussed below, control panel 130 is in fact a removable control panel constructed in accordance with the invention, located in a conventional position.

In addition to the layout described, the control panel may be provided with a pointing device such as a track ball, joystick or other pointing mechanism. In such a manner a user may therefore manipulate a cursor or other pointing embodiment on the display from the control panel. Furthermore, a portion of the control panel may be reprogrammable to include one or more macro buttons, or other user definable portions thereof. Thus, a user may define a sequence of operations to be performed and associate that sequence with a particular control panel button or other indicator. This may allow a user to store such macros that are for complicated sequences for ease of use in the future. Preferable, these macros are stored in the control panel, or in the oscilloscope corresponding to an n identifier of the control panel. So the customizable portion of the control panel may also be provided as a touch screen, with the displays thereon being programmable by the user.

Control panel 130 preferably remains operable when physically disconnected from oscilloscope 100. Thus, control panel maybe adapted to communicate with oscilloscope 100 via a wired cable, a wireless link, or any other communication protocol that allows for signals to be transmitted to and from the control panel for use in controlling the operation of oscilloscope 100, and/or the display of information of display 110/111. Such wireless connection may comprise wireless USB, Bluetooth, wireless LAN, ultra wideband, or any other appropriate wireless communication protocol.

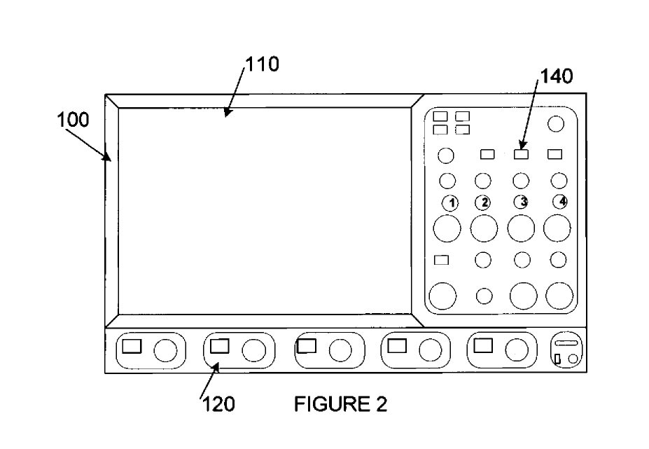

Referring to FIG. 2, control panel 130 may be replaced with an alternate control panel 140 to enable alternate, efficiency-improving shortcut keys and access to task-specific controls. Thus, it is contemplated that one or more alternate control panels may be provided, and use, based at least in part upon the type of measurements to be made by a user. Such an alternate control panel may be the same or a different size that the original control panel. If larger, the alternative control panel may be configured to overhang from the edge of the oscilloscope, or alternatively overhang the display. In such a case, the useable portion of the display may be reduced. Such replaceable functionality also eases the ability to repair the oscilloscope, and any problems with a knob or other portion of the control panel may be remedied simply be replacing the panel.

In addition to providing such an alternative control panel, a so called blanking panel may be provided that may replace the control panel. Such a blanking panel may fit into the control panel location but include no buttons, knobs, or other features, or at least includes a limited number of these features. The blanking panel may be inserted after a user has set up an oscilloscope, and wants to insure that no other person changes any of the settings. Alternatively, the blanking panel may include a designation to lock the oscilloscope as noted above, or allow only for remote control of the oscilloscope.

Each removable control panel or blanking panel may also key the oscilloscope to access a particular option or change the operation mode of the oscilloscope. For example, insertion of a particular control panel, such as a spectrum analyzer panel, may cause the oscilloscope to change modes to operate as a spectrum analyzer. Preferably, the design of the control panel will include function buttons and indicators related to this alternate operation mode. Similarly, insertion of the control panel may cause the oscilloscope to load a particular software option or the like.

In a situation where a user of an oscilloscope may store sensitive information, or make measurements that produce sensitive information, it is contemplated that the control panel or blanking panel includes a flash or other memory storage. Such sensitive information may be stored on this memory, and therefore, a user is able to remove the control or blanking panel along with the sensitive information to a secure location when not in use. In addition to allowing for security, it allows another user to replace another control panel into the oscilloscope and use the oscilloscope without risk of receiving or seeing the sensitive information.

In addition to being removably attached to oscilloscope 100, alternate control panel 140 and control panel may communicate with each other, whether directly or via oscilloscope 100, to exchange information therebetween. Such information may include setup information, user information or the like. In this manner, any information stored in control panel 130 can be easily transferred to alternate control panel 140.

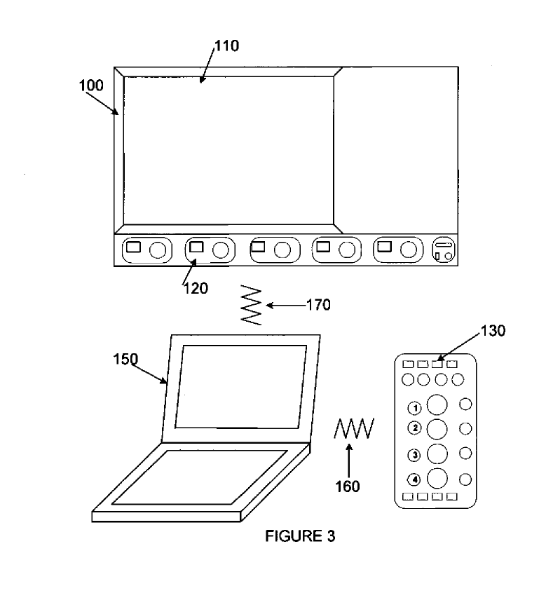

Referring to FIG. 3, control panel 130 may also be connected to a local computing device 150 and the combination may be used to interact remotely with device 100 via connection 170. Thus, such a control panel may be attached to the local computing device via a USB, Bluetooth, or other appropriate wired or wireless connection scheme. Thus, control panel may be adapted to communicate with local computing device 150 via connection 160 which may be a wired cable, a wireless link, or any other communication protocol that allows for signals to be transmitted to and from the control panel for use in controlling the operation of oscilloscope 100 via local computing device 150, and/or the display of information of display 110. Such wireless connection may comprise wireless USB, Bluetooth, wireless LAN, ultra wideband, or any other appropriate wireless communication protocol.

Upon connection thereto, preferable, software contained within local computing device 150 already adapted to control device 100 remotely recognized the control panel 130, or alternate control panel 140. Upon recognition, the local computing device is able to receive commands from the control panel and implement them in controlling the device 100 as if the control panel were still connected to device 100.

An oscilloscope may be provided that includes on or more additional displays. In accordance with the invention, a separate control panel may b e associated with each display. This association may comprise a physical or data transfer connection. In such a case, it is contemplated that each control panel will control the display of information, and the underlying processing of data corresponding to its associated display. Furthermore, each control panel may provide each of the features noted above, such a keying the display into a particular mode of operation, storing sensitive information and the like.

While the invention has been described applicable to an oscilloscope, the invention is intended to be equally applicable to other test and measurement apparatuses and to electronic apparatuses in general.

It will thus be seen that the objects set forth above, among those made apparent from the preceding description, are efficiently attained and, since certain changes may be made in the above construction(s) without departing from the spirit and scope of the invention, it is intended that all matter contained in the above description or shown in the accompanying drawing(s) shall be interpreted as illustrative and not in a limiting sense.

It is also to be understood that the following claims are intended to cover all of the generic and specific features of the invention herein described and all statements of the scope of the invention which, as a matter of language, might be said to fall there between.

What is claimed:

1. A test and measurement apparatus, comprising:
a control panel, wherein the control panel is selectably removable.

2. The test and measurement apparatus of claim 1, wherein upon attachment of the control panel to the test and measurement apparatus, an electrical contact is made.

3. The test and measurement apparatus of claim 1, wherein the control panel is maintained in communicating contact with the test and measurement apparatus when removed via a wired connection.

4. The test and measurement apparatus of claim 1, wherein the control panel is maintained in communication contact with the test and measurement apparatus when removed via a wireless connection.

5. The test and measurement apparatus of claim 1, wherein the removed control panel is operable to control the test and measurement apparatus.

6. The test and measurement apparatus of claim 1, where the control panel is maintained in communicating contact with the test and measurement apparatus via connection to a local computing device remotely controlling the test and measurement apparatus.

7. The test and measurement apparatus of claim 6, wherein the control panel is maintained in communicating contact with the remote computing device when removed via a wired connection.

8. The test and measurement apparatus of claim 6, wherein the control panel is maintained in communication contact with the remote computing device when removed via a wireless connection.

9. The test and measurement apparatus of claim 6, wherein the local computing device controls the test and measurement apparatus via a local area network.

10. The test and measurement apparatus of claim 6, wherein the local computing device controls the test and measurement apparatus via a wireless network.

11. The test and measurement apparatus of claim 1, further comprising a second control panel, the second control panel adapted to be removably attached to the test and measurement device in place of the control panel.

12. The test and measurement apparatus of claim 11, wherein the second control panel has a configuration different from the control panel, and is adapted for use by a user for a purpose different from that of the control panel.

13. The test and measurement apparatus of claim 12, wherein the second control panel includes at least one control not included in the control panel.

14. The test and measurement apparatus of claim 13, wherein the at least one control, when operated, invokes a process on the test and measurement apparatus not accessible when using the control panel.

15. The test and measurement apparatus of claim 11, wherein communication between the control panel, the second control panel and the test and measurement device is managed by utilization of unique IP addresses.

16. The test and measurement apparatus of claim 11, wherein the control panel and the second control panel may communicate directly to exchange information therebetween.

17. The test and measurement apparatus of claim 16, wherein the information comprises setup data.

18. The test and measurement apparatus of claim 16, wherein the information comprises user information.

19. The test and measurement apparatus of claim 11, wherein the control panel and the second control panel may communicate via the test and measurement apparatus to exchange information therebetween.

20. The test and measurement apparatus of claim 1, wherein the test and measurement apparatus is an oscilloscope.

21. The test and measurement instrument of claim 1, further comprising a configuration memory.

22. The test and measurement apparatus of claim 21, wherein the configuration memory is adapted to store user defined information.

23. The test and measurement apparatus of claim 22, wherein the user defined information is used at least in part to configure operation of the test and measurement apparatus.

24. The test and measurement apparatus of claim 1, further comprising a pointing device on the removable control panel for manipulation of a pointing cursor on a display of the test and measurement apparatus.

25. The test and measurement apparatus of claim 1 further comprising one or more programmable buttons on the removable control panel, each of the programmable buttons being programmable to perform one or more processes on the test and measurement apparatus.

26. The test and measurement apparatus of claim 1, farther comprising a programmable touch screen on the removable control panel.

27. The test and measurement apparatus of claim 26, wherein the programmable touch screen is programmable to provide one or more controllers to control one or more processes on the test and measurement apparatus.

28. The test and measurement apparatus of claim 1, further comprising a blanking panel, the blanking panel adapted to be removably attached to the test and measurement device in place of the control panel.

29. The test and measurement apparatus of claim 28, wherein upon installation of the blanking panel, adjustment of the test and measurement apparatus is disabled.

30. The test and measurement apparatus of claim 28, wherein upon installation of the blanking panel, control of the test and measurement apparatus may only be performed remotely.

31. The test and measurement apparatus of claim 28, further comprising a storage device maintained within the blanking panel, wherein information from the test and measurement apparatus is stored on the storage device, and wherein upon removal of the blanking panel, this sensitive information is removed from the test and measurement apparatus.

32. The test and measurement apparatus of claim 1, wherein attachment of the removable control panel launches installation of a software option on the test and measurement apparatus associated with the removable control panel.

33. The test and measurement apparatus of claim 1, wherein attachment of the removable control panel places the test and measurement apparatus in an operation mode associated with the removable control panel.

34. The test and measurement apparatus of claim 1 including a primary and a supplemental display, comprising:
a supplemental control panel associated with the supplemental display, wherein the supplemental display controls the display and processing of information corresponding to the supplemental display.
